(19) United States
(12) Patent Application Publication
(10) Pub. No.: US 2018/0143251 A1
(43) Pub. Date: May 24, 2018

(54) Portable Troubleshooting Relay Electric Testing Device

(71) Applicant: Sotiraq L Tili, Quincy, MA (US)

(72) Inventor: Sotiraq L Tili, Quincy, MA (US)

(21) Appl. No.: 15/358,566

(22) Filed: Nov. 22, 2016

(51) Int. Cl. G01R 31/327; G07C 5/08

(52) U.S. Cl. CPC G01R 31/3278; G07C 5/0816

(57) ABSTRACT

An electrical relay testing device that provides color-coded indicator lights to test vehicle circuit boards for any 12 volt or 24 volt systems, drawing 15 to 150 amps. The device contains an internal relay, standard relay terminal connections, and at least two external indicator lights. Once the device is plugged into a vehicle circuit board, if the relay terminals are properly working on the board, both lights will illuminate. This device greatly simplifies the process of troubleshooting electrical and electronic systems of vehicles.

### FIELD OF THE INVENTION

The subject invention is a quick, simple, and portable electrical relay testing device that provides color-coded indicator lights to test vehicle circuit boards, for use by professional mechanics.

### BACKGROUND OF INVENTION

Electromechanical relays are used extensively in low voltage vehicle electrical systems. A typical vehicle can help 20 or more relays. A relay is a remote control switch that is operated electrically rather than mechanically. Relays permit a small current flow circuit to control a higher current circuit.

Electro-mechanical relays work by activating an electromagnet to pull a set of contacts to make or break an internal circuit.

A copper coil wrapped around an iron core forms the electromagnet within the relay. This electromagnet is held in a frame to a hinged soft iron bar, or armature. One end of the armature is connected to a tension spring that pulls the other end of the armature up. This is the relay in its de-energized state or at rest with no voltage applied. The coil and contacts are then connected to various terminals on the outside of the relay.

When a voltage is supplied to the coil (by switching on the relay), it creates a small magnetic field around it, this magnetic field overcomes the pulling force provided by the spring and moves the hinged armature down onto, or away from, the contact, such that the circuit is either now either broken or connected. This completes the current circuit between the terminals and the relay is energized. When voltage is removed from the coil terminal the spring pulls the armature back into it's rest position and breaks the circuit between the terminals. So, by applying or removing power to the coil, the relay switches the high current circuit on or off. If the armature/contact is broken with the relay at rest, then the relay is referred to as Normally Open (NO). If the armature/contact is closed with the relay at rest, then the relay is referred to as Normally Closed (NC). These relays are known as Make & break relays or Single Pole Single Throw (SPST).

Electromechanical relays are used widely in vehicle electrical systems due to relatively low cost, and the ability to deploy a large number of relays together to carry out complex functions.

Electromechanical relays are typically not equipped with self-monitoring equipment. In a system with multiple interconnected relays, any malfunction of one of the relays can lead to a complete system failure. When the system malfunctions, it can be significantly cumbersome for maintenance personnel to trace the faulty relay. Often, it can be difficult to diagnose and correct any electrical issues since the circuit boards show no signs of failure. A trial and error method may be employed, that replaces each relay before powering up and running the system to verify if the relay problem has been resolved. If the failed relay is unresolved, the process is repeated. Thus, the troubleshooting process can be time consuming and expensive.

Therefore, there exists a need to provide a quick, inexpensive, easy-to-use system to test individual relays within complex vehicle electrical systems for failure.

### SUMMARY OF THE INVENTION

There are additional features of the invention that will be described hereinafter and which will form the subject matter of the claims appended hereto. In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting

The subject invention discloses a relay testing device comprising: a portable handheld housing comprising a plurality of protruding male pins operatively connected to internal terminals; an internal switch assembly comprising an electromagnetic coil and an armature, wherein the electromagnetic coil and armature energize the relay testing device upon successful voltage applied from a circuit board; a first external light source on the housing, wherein the first light source illuminates upon voltage received by the electromagnetic coil; and a second external light source on the housing, wherein the second light source illuminates upon energization of the relay testing device.

The subject invention also discloses a relay testing device comprising: a portable handheld housing comprising a plurality of protruding male pins operatively connected to internal terminals; an internal switch assembly comprising an electromagnetic coil and an armature, wherein the electromagnetic coil and armature energize the relay testing device upon successful voltage applied from a circuit board; a first external light source on the housing, wherein the first light source illuminates upon an absence voltage applied, but not received by the electromagnetic coil; a second external light source on the housing, wherein the second light source illuminates upon voltage received by the electromagnetic coil; and a third external light source on the housing, wherein the third light source illuminates upon energization of the relay testing device.

The subject invention also discloses a relay testing device comprising: a portable handheld housing comprising a plurality of protruding male pins operatively connected to a plurality of internal terminals; an internal switch assembly that energizes the relay testing device upon successful voltage applied from a circuit board; a first external light source on the housing that illuminates upon voltage received by the testing device; and a second external light source on the housing, wherein the second light source illuminates upon energization of the relay testing device.

The subject invention also discloses a relay testing device comprising: a portable handheld housing comprising a plurality of protruding male pins operatively connected to a plurality of internal terminals; an internal switch assembly that energizes the relay testing device upon successful voltage applied from a circuit board; a first external light source on the housing that illuminates upon voltage applied, but not received by the testing device; a second external light source on the housing that illuminates upon voltage received by the testing device; and a third external light source on the housing, wherein the second light source illuminates upon energization of the relay testing device.

The subject invention also discloses a relay testing device comprising: a portable handheld housing; a first terminal within the housing operatively connected to a first protruding male pin external to the housing, wherein the first terminal is operatively connected to a first external light source on the housing, further wherein the first light source illuminates upon voltage received by the testing device from a female socket in a circuit board; a second terminal within the housing operatively connected to a second protruding male pin external to the housing; a third terminal within the housing operatively connected to a third protruding male pin external to the housing, wherein the third terminal is operatively connected to a second external light source on the housing; a fourth terminal within the housing operatively connected to a fourth protruding male pin external to the housing; an electromagnetic coil within the housing operatively connected to at the first and second terminal, wherein the electromagnetic coil emits a small magnetic field upon receive voltage from the first terminal; and an armature within the housing operatively connected on a first end to the third terminal, wherein the armature is configured to move an uncontacted second end to contact the fourth terminal upon application of the small magnetic field from the electromagnetic coil, further wherein the second light source illuminates upon successful contact of the second end of the armature to the fourth terminal.

The subject invention also discloses a relay testing device comprising: a portable handheld housing; a first terminal within the housing operatively connected to a first protruding male pin external to the housing, wherein the first terminal is operatively connected to a first external light source and a second external light source on the housing, further wherein the first light source illuminates upon voltage applied, but not received by the testing device from a female socket in a circuit board, wherein the second light source illuminates upon voltage received by the testing device from the circuit board; a second terminal within the housing operatively connected to a second protruding male pin external to the housing; a third terminal within the housing operatively connected to a third protruding male pin external to the housing, wherein the third terminal is operatively connected to a third external light source on the housing; a fourth terminal within the housing operatively connected to a fourth protruding male pin external to the housing; an electromagnetic coil within the housing operatively connected to at the first and second terminal, wherein the electromagnetic coil emits a small magnetic field upon receive voltage from the first terminal; and an armature within the housing operatively connected on a first end to the third terminal, wherein the armature is configured to move an uncontacted second end to contact the fourth terminal upon application of the small magnetic field from the electromagnetic coil, further wherein the third light source illuminates upon successful contact of the second end of the armature to the fourth terminal.

In a further embodiment of the subject invention, the relay testing device is re-useable for testing multiple circuit boards.

In a further embodiment of the subject invention, the light sources each comprise light emitting diodes.

In a further embodiment of the subject invention, the light sources may visible red or green light.

In a further embodiment of the subject invention, the light indication may be provided in a single window on the exterior of the housing.

In a further embodiment of the subject invention, the light indication may be provided in two windows on the exterior of the housing.

In a further embodiment of the subject invention, the relay testing device may comprise a housing and pins substantially similar to relay DIN 72552.

In a further embodiment of the subject invention, the circuit board may comprise a 12 volt or 24-volt board from vehicle electrical systems.

In embodiments of the subject invention, the relays may be used with systems using 10 to 100 amperage.

In a further embodiment of the subject invention, the vehicle may comprise any land-based vehicles having pneumatic tires, any rail-based vehicles, any maglev vehicles, automobiles, cars, trucks, station wagons, sport-utility vehicles (SUVs), recreational vehicles, construction vehicles, off road vehicles, all-terrain vehicles, farm vehicles, fleet vehicles, motor homes, vans, buses, motorcycles, scooters, mopeds, campers, trailers, bicycles, a marine vehicle, an air vehicle, spacecraft, airplanes, jets, aircraft, airships, balloons, blimps, dirigibles, or another motor vehicle.

There has thus been outlined, rather broadly, the more important features of the invention in order that the detailed description thereof that follows may be better understood, and in order that the present contribution to the art may be better appreciated. There are additional features of the invention that will be described hereinafter and which will form the subject matter of the claims appended hereto. These together with other objects of the invention, along with the various features of novelty, which characterize the invention, are pointed out with particularity in the claims annexed to and forming a part of this disclosure.

### BRIEF DESCRIPTION OF THE DRAWINGS

Advantages of the present invention will be apparent from the following detailed description of exemplary embodiments thereof, which description should be considered in conjunction with the accompanying drawings:

FIG. 1 is a schematic view of a standard single pole single throw relay and its four Terminals/Pins electrical connections on a vehicle electrical system which may be 12 volts to 24 volts, and 10 amps to 100 amps.

FIG. 2 is a bottom view of a single pole single throw relay with four Terminals/Pins, which may be used on an electrical system that is 12 volts to 24 volts, and 10 amps to 100 amps.

FIG. 3 is a schematic view of a standard single pole single throw relay with four Terminals/Pins in the Normally Open, or de-energized position, which may be used on an electrical system that is 12 volts to 24 volts, and 10 amps to 100 amps.

FIG. 4 is a schematic view of a standard single pole single throw relay with four Terminals/Pins in the energized position, which may be used on an electrical system that is 12 volts to 24 volts, and 10 amps to 100 amps.

FIG. 5 is a bottom view of a single pole single throw relay with six Terminals/Pins, which may be used on an electrical system that is AC 120 volts, and 10 amps to 30 amps.

FIG. 6 is a schematic view of a standard single pole single throw relay with six Terminals/Pins in the Normally Open, or de-energized position, which may be used on an electrical system that is AC 120 volts, and 10 amps to 30 amps.

FIG. 7 is a schematic view of a standard single pole single throw relay with six Terminals/Pins in the energized position, which may be used on an electrical system that is AC 120 volts, and 10 amps to 30 amps.

FIG. 8 is a schematic view of troubleshooting relay testing device with four Terminals/Pins in the de-energized position, which may be used on an electrical system that is 12 volts to 24 volts, and 10 amps to 100 amps.

FIG. 9 is a schematic view of troubleshooting relay testing device with four Terminals/Pins in the energized position and the LEDs illuminated, which may be used on an electrical system that is 12 volts to 24 volts, and 10 amps to 100 amps.

FIG. 10 is a schematic view of troubleshooting relay testing device with six Terminals/Pins in the de-energized position, which may be used on an electrical system that is AC 120 volts, and 10 amps to 30 amps.

FIG. 11 is a schematic view of troubleshooting relay testing device with six Terminals/Pins in the energized position and the LEDs illuminated, which may be used on an electrical system that is AC 120 volts, and 10 amps to 30 amps.

FIG. 12 is an exterior view of the limit switch tester for all Telemecanique® or Schneider Electric® switches.

FIG. 13 is a schematicview of the limit switch tester for Telemecanique® or Schneider Electric® switches.

FIG. 14 is another schematic view of the limit switch tester for Telemecanique® or Schneider Electric® switches.

FIG. 15 is a schematic view of the tester for limit switches with green and red LEDs with a 3-volt battery.

FIG. 16 is another schematic view of the tester for limit switches with green and red LEDs with a 3-volt battery.

FIG. 17 is a schematic view of the single pole single with green and red LEDs, which may be used on an electrical system that is AC 120 volts, and 10 amps to 30 amps.

FIG. 18 is a schematic view of the single pole double with green and red LEDs, which may be used on an electrical system that is AC 120 volts, and 10 amps to 30 amps.

### DETAILED DESCRIPTION OF EMBODIMENTS

While several variations of the present invention have been illustrated by way of example in particular embodiments, it is apparent that further embodiments could be developed within the spirit and scope of the present invention, or the inventive concept thereof. However, it is to be expressly understood that such modifications and adaptations are within the spirit and scope of the present invention, and are inclusive, but not limited to the following appended claims as set forth.

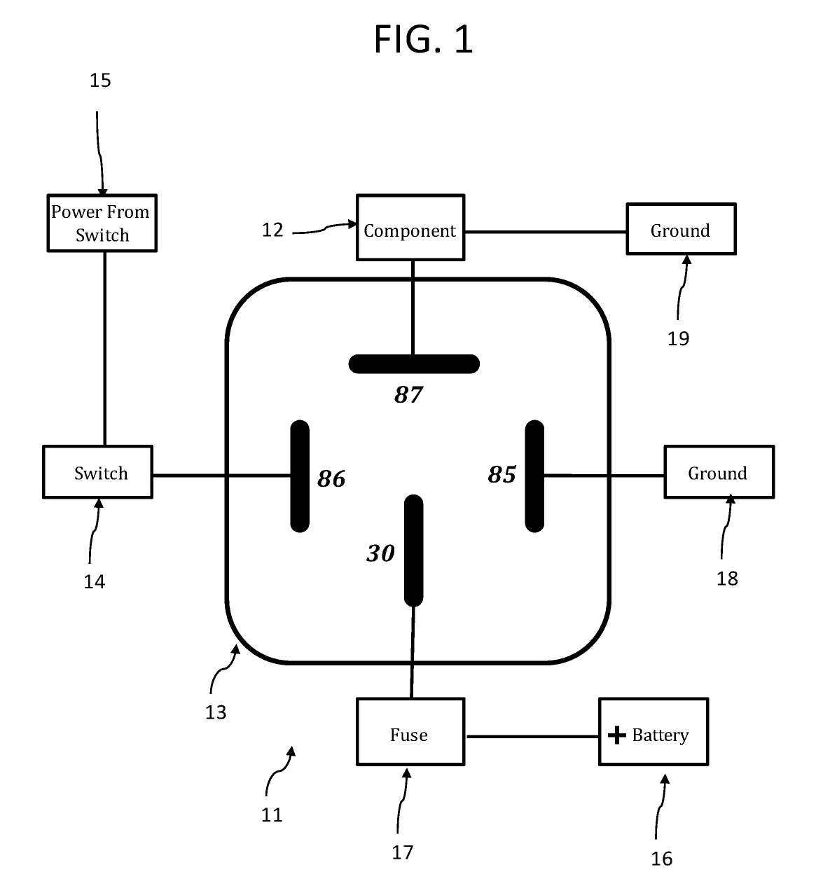

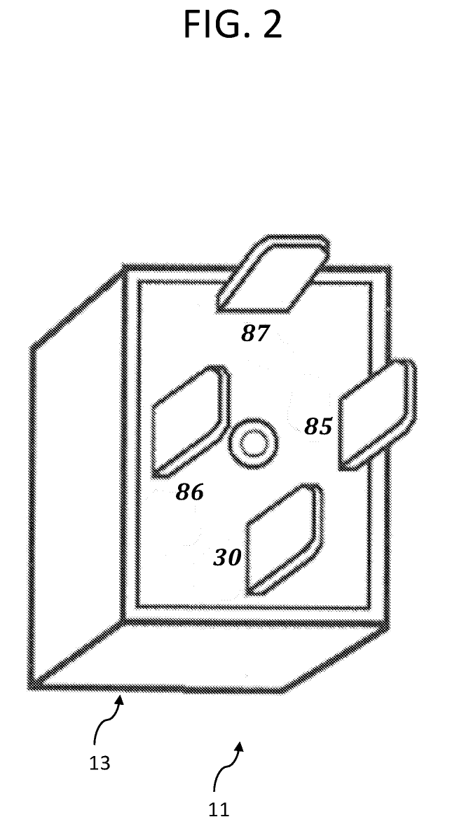

FIGS. 1-4 illustrate a standard make and break, or Single Pole Single Throw (SPST) relay 11 with four Terminals/Pins for operating a vehicle circuit component 12 (such as the control circuit for automobile headlights, horn, fuel pump, and electric fan). The relay 11 has a generally cuboid shape casing 13 with four protruding male Terminals/Pins 85, 86, 87, and 30. The Terminals/Pins 85, 86, 87, and 30 are taken from DIN 72552. This is a German automotive industry standard that has been widely adopted and allocates a numeric code to various types of electrical terminals found in vehicles. The relay 11 is operatively attached to a vehicle circuit board by inserting the four protruding male Terminals/Pins 85, 86, 87, and 30 into four female sockets on the board.

Once inserted, a switch 14, with a power source 15 controls the relay 11 through the relay switch power lead Terminal/Pin 86. The relay 11 then provides a direct connection from a battery 16 through a fuse 17 to Terminal/Pin 30 to the relay power lead Terminal/Pin 87 which provides power to the component 12. The lead Terminal/Pin 85 separately grounds 18 the relay 11 from the ground 19 of the component 12. Terminals/Pins 85 and 86 are connected to an internal electromagnetic coil 20. Terminal/Pin 87 is connected to the Normally Open (NO) contact 21 of the armature 22. The internal electromagnetic coil 20 is fed with +12V or +24V to Terminal/Pin 86 and grounded via Terminal/Pin 85. The amperage of such electrical systems may be 10 to 100 amps. This electromagnet coil 20 is held in a frame to the armature 22. One end of the armature 22 is connected to a tension spring that pulls the other end, or the Normally Open (NO) contact 21 of the armature 22 up. This is the relay 1 in its de-energized state or at rest with no voltage applied.

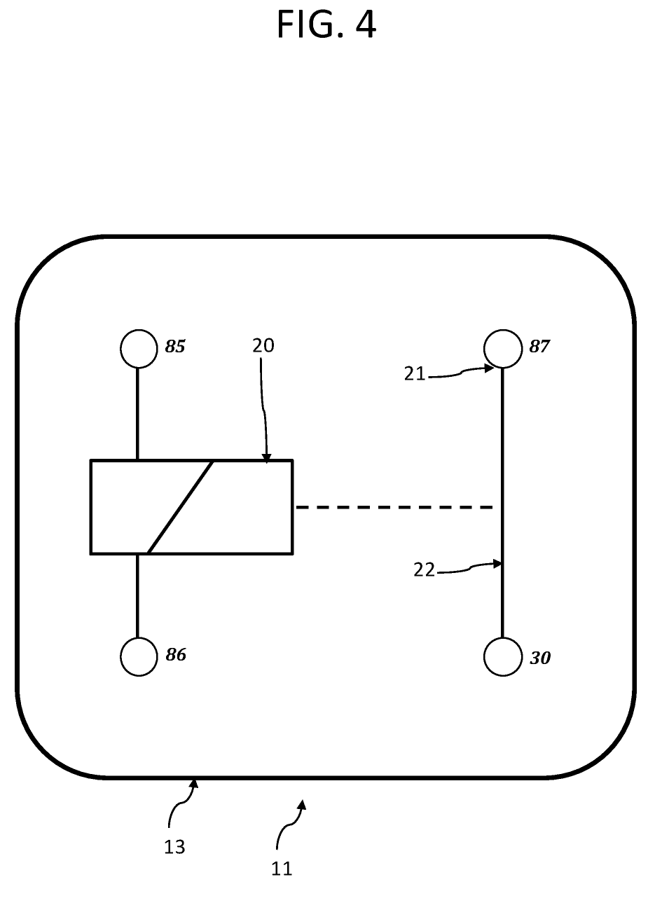

As illustrated in FIG. 4, when the Switch 13 is activated, a voltage is supplied to the coil 20 through Terminal/Pin 86, which creates a small magnetic field around the coil 20. This magnetic field overcomes the pulling force provided by the spring and moves the hinged armature 22 down onto Normally Open (NO) contact 21. This connects the battery 16 through Terminal/Pin 87 to the component 12 through Terminal/Pin 30, so that the circuit is now connected. This completes the current circuit between Terminals/Pins 85, 86, 87, and 30 and the relay 11 is energized.

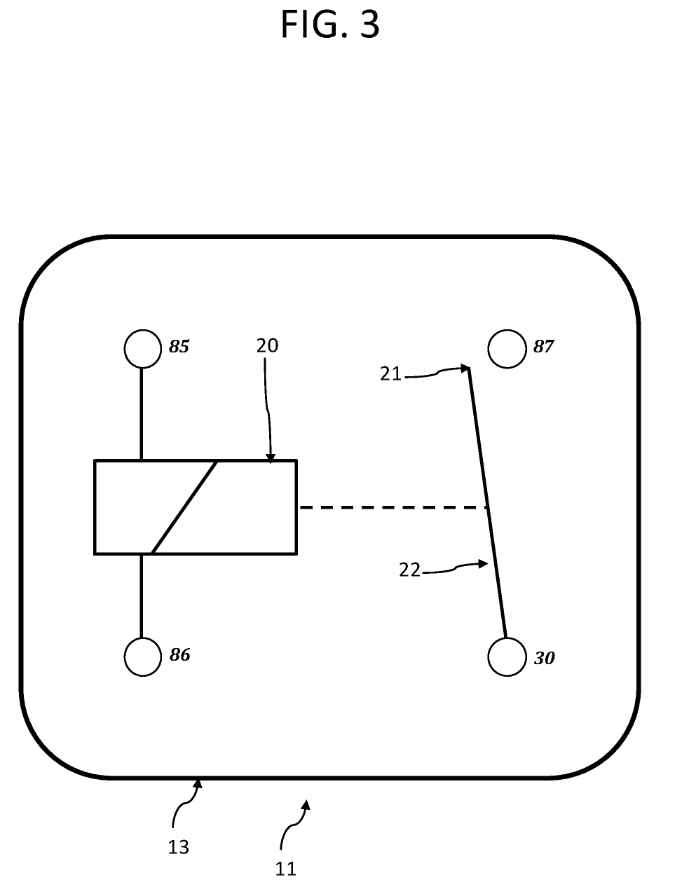

As illustrated in FIG. 3, when the Switch 13 is de-activated, a voltage is removed from the coil 20 through Terminal/Pin 86, which ends the small magnetic field around the coil 20. The spring moves the hinged armature 22 back away from Normally Open (NO) contact 21, breaking the circuit. This dis-connects Terminal/Pin 87 and Terminal/Pin 30, disconnecting the battery 16 from component 12. The relay 11 is now dis-energized.

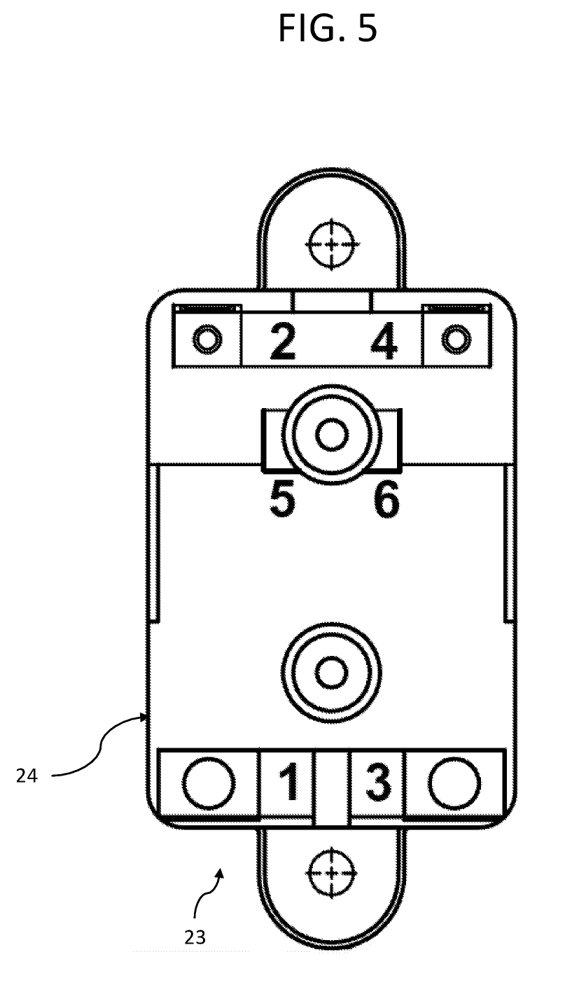

FIGS. 5-7 illustrate a standard make and break, or Single Pole Single Throw (SPST) relay 23 with six Terminals/Pins for operating a vehicle circuit component (such as the control circuit for automobile headlights, horn, fuel pump, and electric fan). The relay 23 has a generally cuboid shape casing 24 with six protruding male Terminals/Pins 1, 2, 3, 4, 5, and 6. The relay 23 is operatively attached to a vehicle circuit board by inserting the six protruding male Terminals/Pins 1, 2, 3, 4, 5, and 6 into six female sockets on the board. Terminals/Pins 1 and 3 are connected to an internal electromagnetic coil 25. Terminal/Pins 2 and 4 form the Normally Open (NO) contact 26. Terminal/Pins 5 and 6 form the Normally Closed (NC) contact 27. The internal electromagnetic coil 25 is fed with +12V or +24V to Terminal/Pin 1 and grounded via Terminal/Pin 3. The amperage of such electrical systems may be 10 to 100 amps. The relay 23 may also be used on electrical systems that are AC 120 volts and 10 to 30 amps.

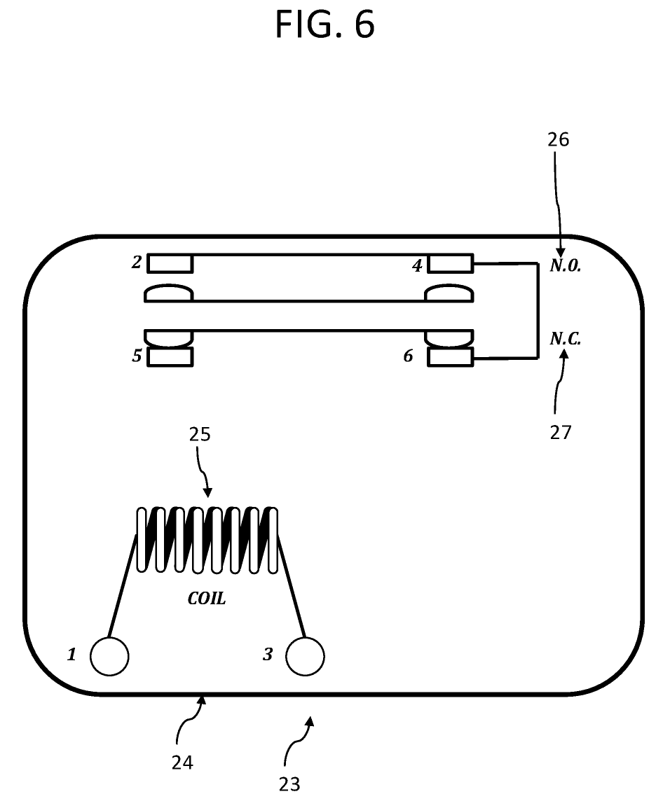

As illustrated in FIG. 6, when the relay 23 is de-activated, a voltage is removed from the coil 25 through Terminal/Pin 3, which ends the small magnetic field around the coil 25. This breaks contact between Terminal/Pins 2 and 4 from Normally Open (NO) contact 26, breaking the circuit. The relay 23 is now dis-energized.

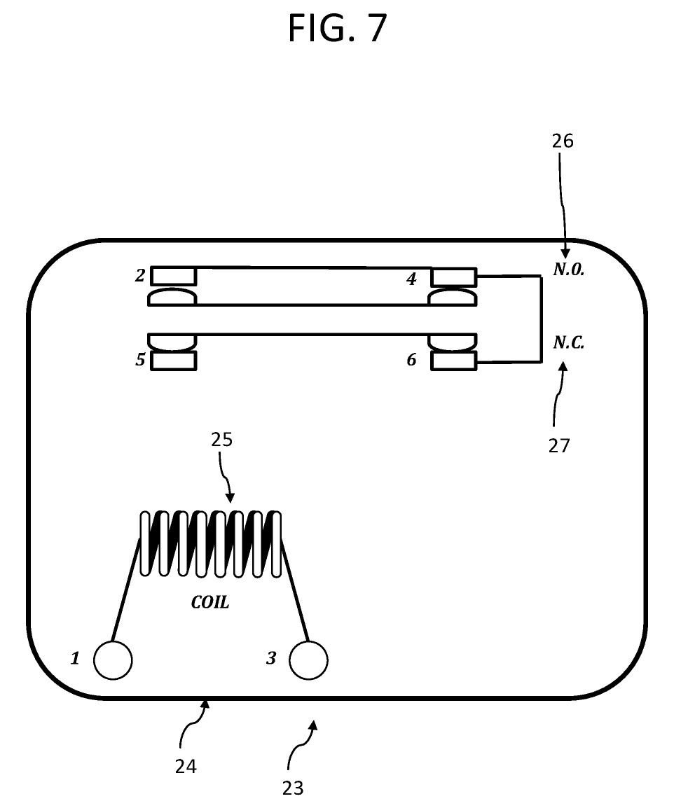

As illustrated in FIG. 7, when the relay 23 is activated, a voltage is supplied to the coil 25 through Terminal/Pin 1, which creates a small magnetic field around the coil 25. This magnetic field brings contact between Terminal/Pins 2 and 4 from Normally Open (NO) contact 26 so that the circuit is now connected.

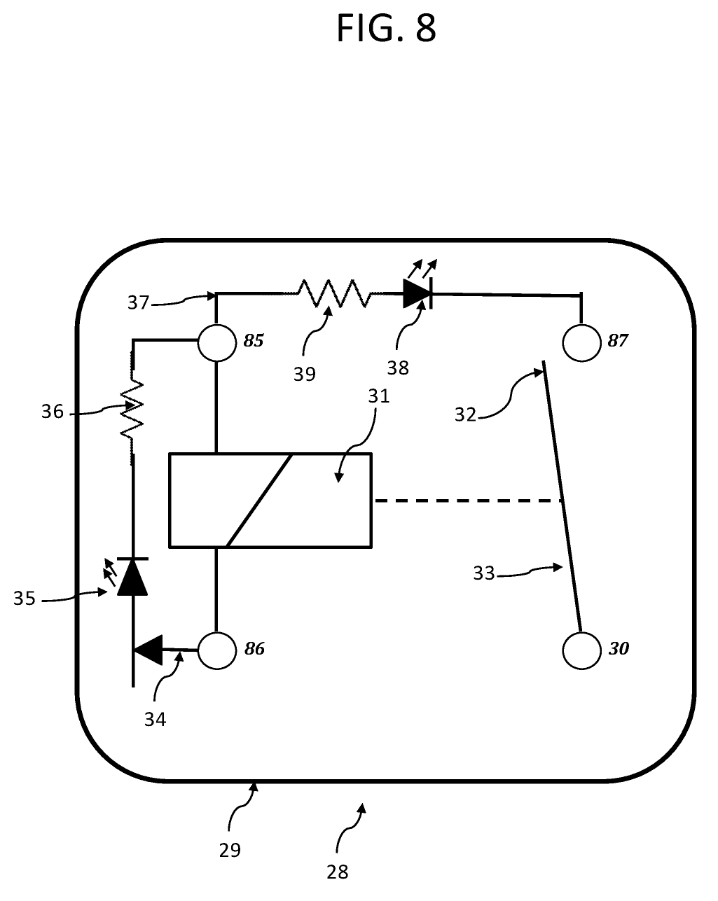

Embodiments of the subject invention are disclosed in FIGS. 8-11. The first embodiment of a troubleshooting relay device 28 tests four Terminal/Pin relays 11. The troubleshooting relay device 28 has a generally cuboid shape casing 29 with four protruding male Terminals/Pins 85, 86, 87, and 30, substantially similar to relay 11. In embodiments of the subject invention, the outer casing 29 may be composed of a strong, durable plastic, such as high density polyethylene or polypropylene

In the troubleshooting relay device 28, Terminals/Pins 85 and 86 are connected to an internal electromagnetic coil 31. Terminal/Pin 87 is connected to Normally Open (NO) contact 32 of an armature 33. Terminal/Pin 30 is connected to armature 33. This electromagnetic coil 31 is held in a frame to the armature 33. One end of the armature 33 is connected to a tension spring that pulls the other end, or the Normally Open (NO) contact 32 of the armature 33 up. This is the troubleshooting relay device 28 in its de-energized state or at rest with no voltage applied.

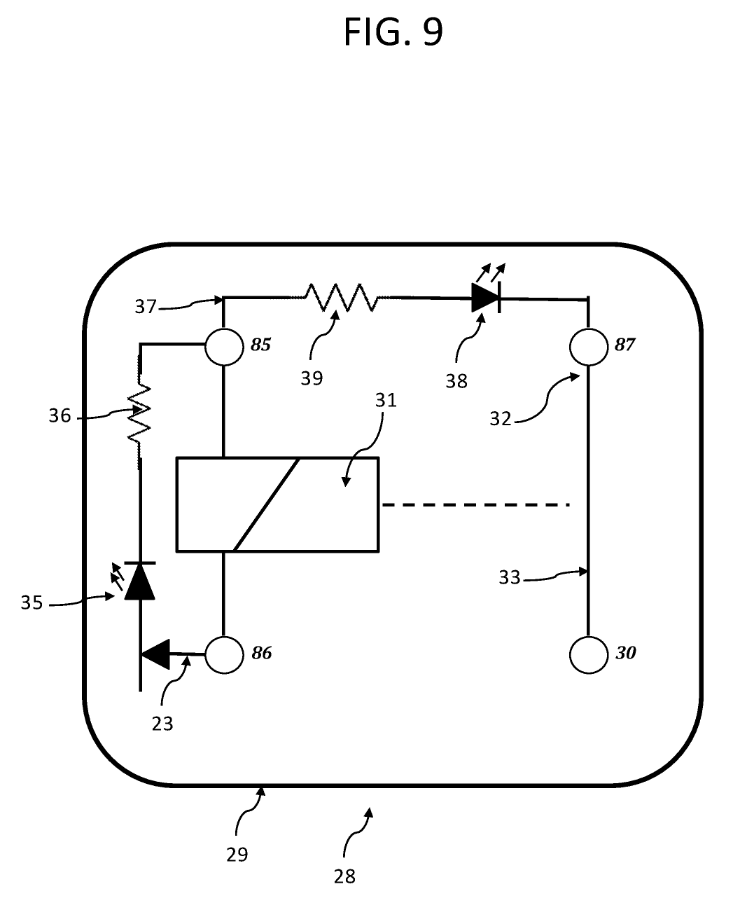

FIGS. 8 and 9 illustrate a first embodiment of the troubleshooting relay device 28. In this embodiment, a connection 34 is made between Terminal/Pin 86 and Terminal/Pin 85. This connection 34 contains a first light emitting diode (LED) 35 and a resistor 36. If Terminal/Pin 86 receives voltage from switch 4, then connection 34 provides power to the first LED 35 to illuminate a first color on the exterior of the troubleshooting relay device 28 casing 29. Another connection 37 is made between Terminal/Pin 87 and Terminal/Pin 30. This connection 37 contains a second LED 38 and a resistor 39. If the coil 31 receives voltage, a small magnetic field around the coil 31 overcomes the pulling force provided by the spring and moves the hinged armature 33 down onto Normally Open (NO) contact 32. The connection 37 is made between Terminal/Pin 87 and Terminal/Pin 30, powering the second LED 38 to illuminate a second color on the exterior of the troubleshooting relay device 28 casing 29.

To troubleshoot, or quickly test, the functionality of a relay 1 or a vehicle circuit board using this first embodiment of the troubleshooting relay device 28, the relay 1 is removed from the four female sockets. The troubleshooting relay device 28 is then inserted onto the vehicle circuit board by inserting its four protruding male Terminals/Pins 85, 86, 87, and 30 into four female sockets on the board. The troubleshooting relay device 28 may be used on an electrical system that is 12 volts to 24 volts, and 10 amps to 100 amps.

Once inserted, if the board is working properly, the switch 4 will provide power to the troubleshooting relay device 28 Terminal/Pin 86. Once the voltage is received through Terminal/Pin 86, the connection 34 is made to power the first LED 35 to illuminate a first color on the exterior of the troubleshooting relay device 28 casing 29. This first illuminated LED 35 quickly informs the user that the relay connection is properly receiving power from the board. If the coil 31 receives power from Terminal/Pin 86, a small magnetic field around the coil 31 overcomes the pulling force provided by the spring and moves the hinged armature 33 down onto Normally Open (NO) contact 32 to make connection 37 is made between Terminal/Pin 87 and Terminal/Pin 30. This powers the second LED 38 to illuminate a second color on the exterior of the troubleshooting relay device 28 casing 29. This second illuminated LED 38 quickly informs the user that the internal coil of the relay connection is properly receiving power from the board.

Once the test is complete the troubleshooting relay device 28 is removed from the four female sockets, and used on the next relay 1 site to be tested. This enables a user to quickly and efficiently insert and re-insert the troubleshooting relay device 28, and look for the two illuminated LEDs 35 and 38 to test the relays 1 of the vehicle electrical system.

In embodiments of the subject invention, the first LED 35 and the second LED 38 illuminate distinctly colored lights, preferably a red color for LED 35 and a green color for LED 38.

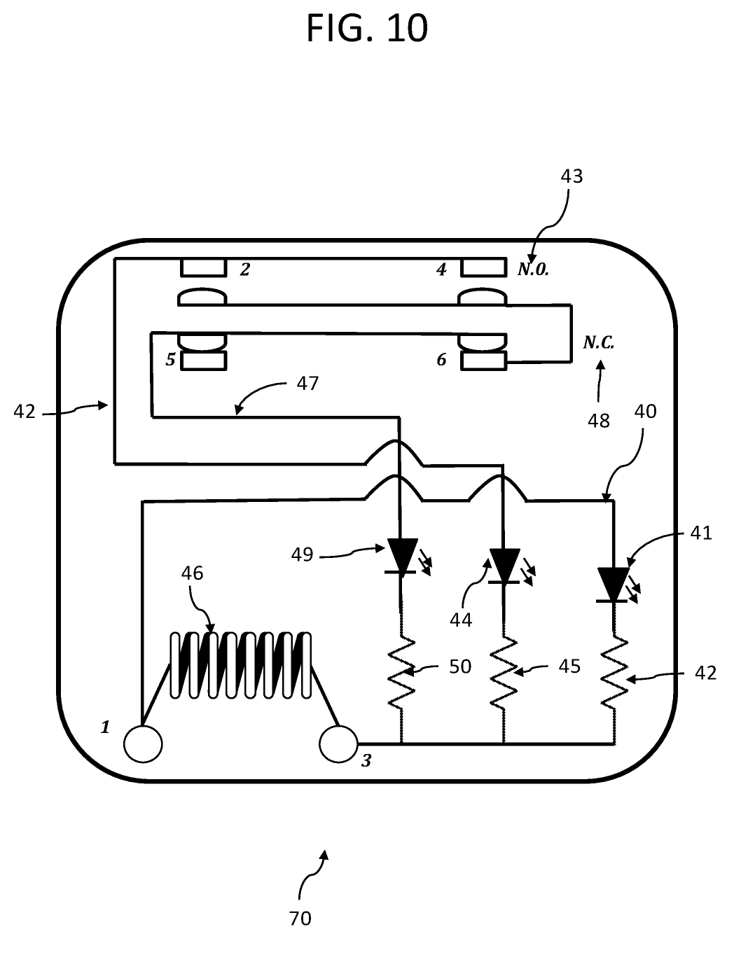

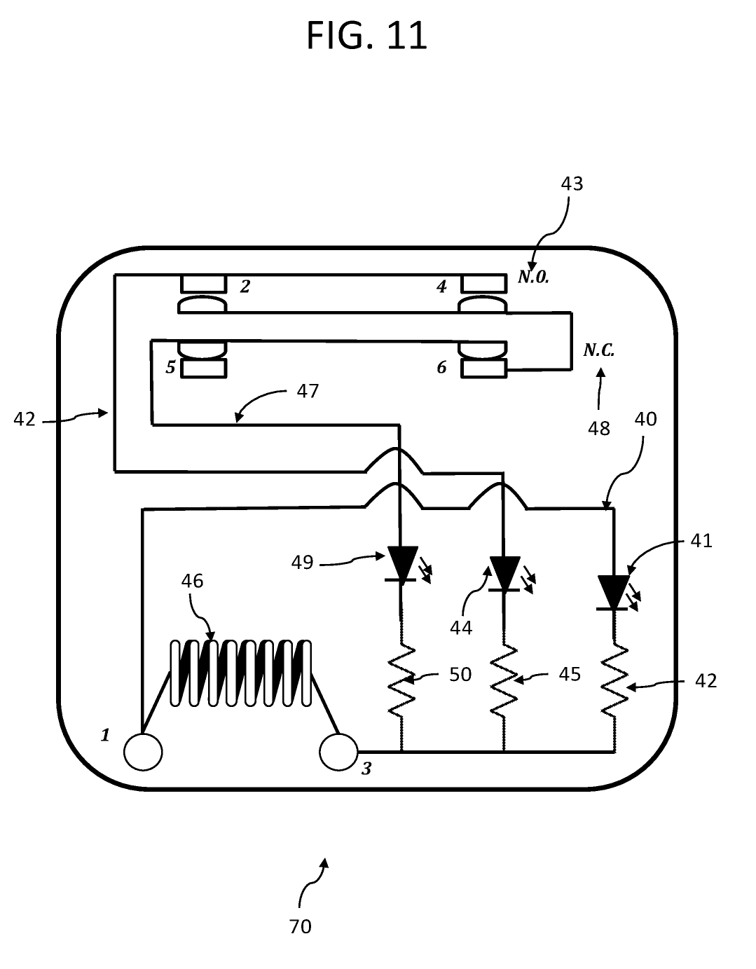

FIGS. 10 and 11 illustrate a second embodiment of the troubleshooting relay device 70 for use with six Terminal/Pin relays. In this embodiment, a first connection 40 is made between Terminal/Pin 1 and Terminal/Pin 3. This first connection 40 contains a first light emitting diode (LED) 41 and a resistor 42. If Terminal/Pin 1 receives voltage from switch 4, then connection 40 provides power to the first LED 41 to illuminate a first color on the exterior of the troubleshooting relay device 70. A second connection 42 is made between Terminal/Pins 2 and 4, the Normally Open (NO) contact 43, and Terminal/Pin 3. This second connection 42 contains a second LED 44 and a resistor 45. If a coil 46 receives voltage, the second connection 42 is made between Terminal/Pins 2, 4, and 3 powering the second LED 44 to illuminate a second color on the exterior of the troubleshooting relay device 70. A third connection 47 is made between Terminal/Pins 5 and 6, the Normally Closed (NC) contact 48, and Terminal/Pin 3. This third connection 47 contains a third LED 49 and a resistor 50. If the coil 46 does not receive a voltage, the third connection 47 is made between Terminal/Pins 5 and 6, the Normally Closed (NC) contact 48, and Terminal/Pin 3, powering the third LED 49 to illuminate a third color on the exterior of the troubleshooting relay device 70.

Once this embodiment of the device is inserted in a board to be tested, if the board is working properly, the switch 4 will provide power to the troubleshooting relay device 70 Terminal/Pin 1.

Once the voltage is received through Terminal/Pin 1, the first connection 40 contains powers the first light emitting diode (LED) 41 to illuminate a first color on the exterior of the troubleshooting relay device 70. This first illuminated LED 41 quickly informs the user that the relay connection is properly receiving power from the board. If a coil 46 receives voltage, the second connection 42 powers the second LED 44 to illuminate a second color on the exterior of the troubleshooting relay device 70. This second illuminated LED 44 quickly informs the user that the internal coil of the relay connection is properly receiving power from the board. If the coil 46 does not receive a voltage, the third connection 47 powers the third LED 49 to illuminate a third color on the exterior of the troubleshooting relay device 70. This third illuminated LED 49 quickly informs the user that the internal coil of the relay connection is properly receiving power from the board.

Once the test is complete the troubleshooting relay device 70 is removed from the six female sockets, and used on the next relay 1 site to be tested. This enables a user to quickly and efficiently insert and re-insert the troubleshooting relay device 39, and look for the three illuminated LEDs 41, 44, and 49 to test the relays 1 of the vehicle electrical system. The troubleshooting relay device 70 may also be used on electrical systems that are AC 120 volts and 10 to 30 amps.

In embodiments of the subject invention, the three illuminated LEDs 41, 44, and 49 illuminate distinctly colored lights.

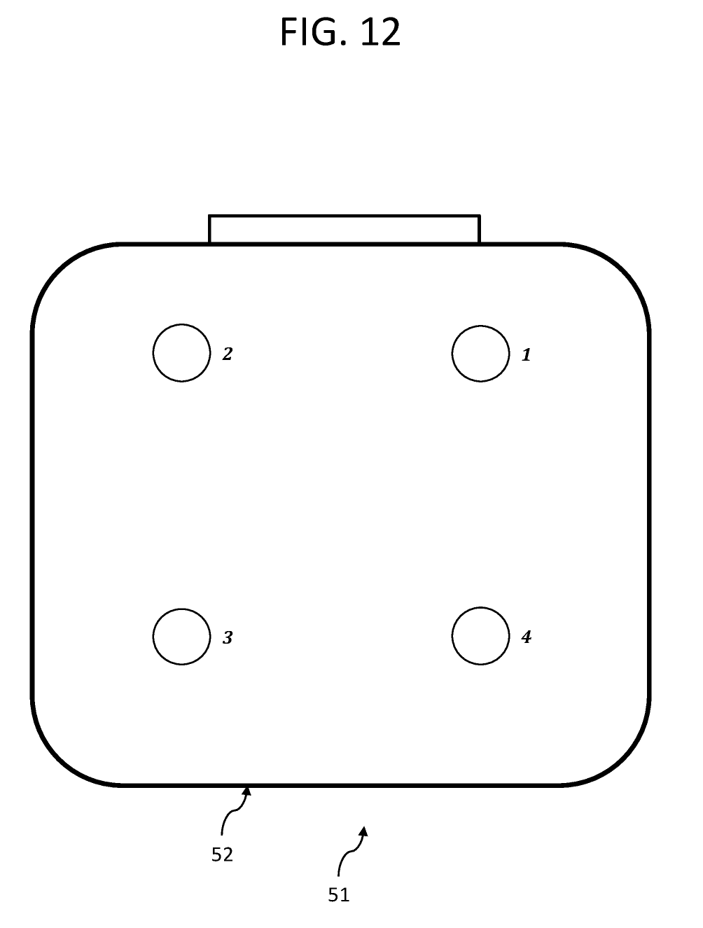

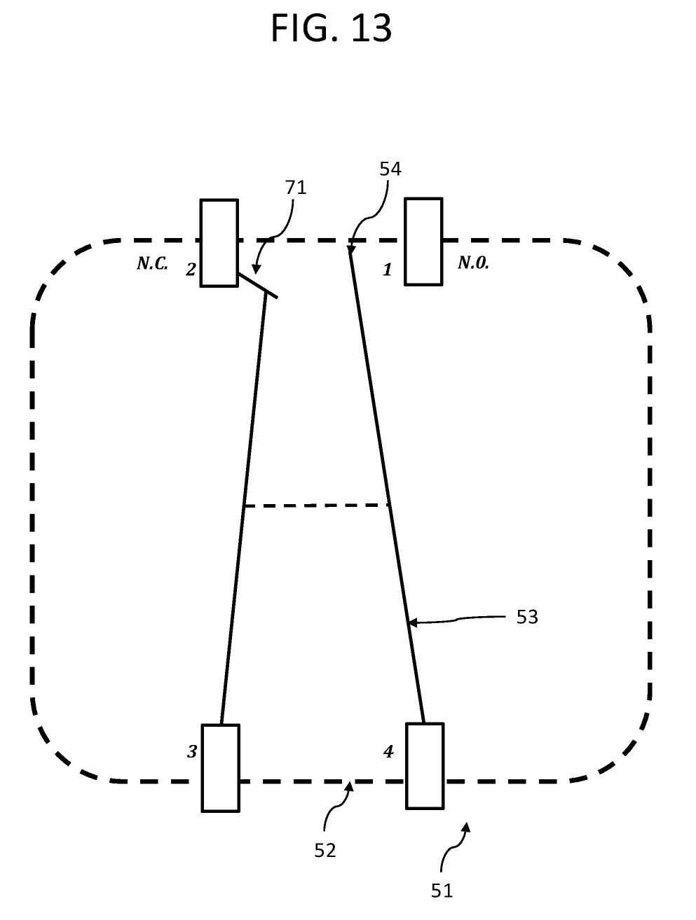

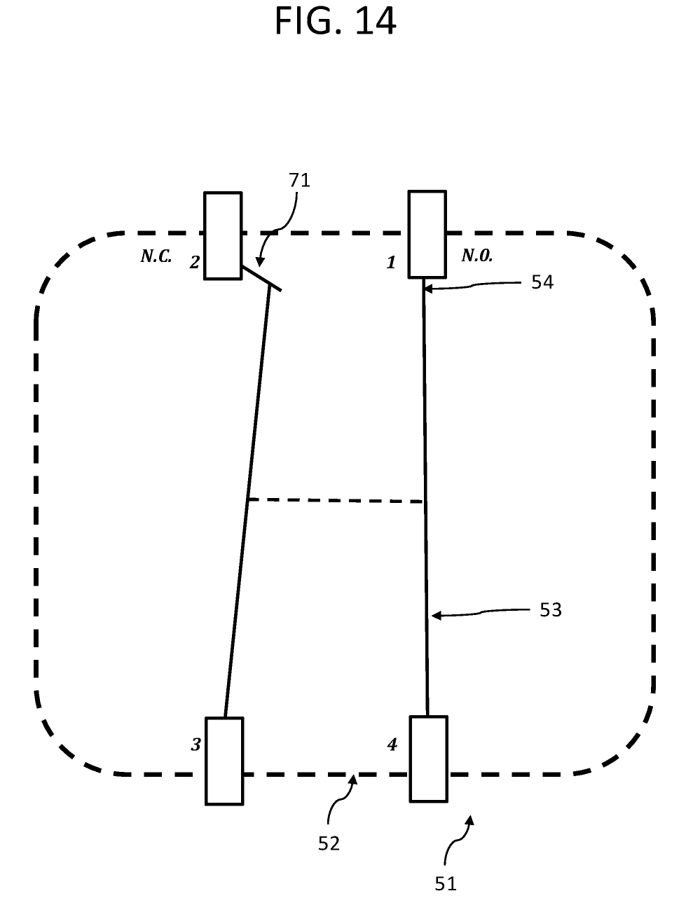

FIGS. 12-18 illustrate embodiments of a tester 51 for Telemecanique® or Schneider Electric® limit switches. The tester 51 has a generally cuboid shape casing 52 with four female pin receptors 1, 2, 3, and 4. Female pin receptors 2 and 3 are connected to the Normally Closed (NC) contact 71. Female pin receptors 2 and 3 are connected to the Normally Closed (NC) contact 71. Female pin receptor 4 is attached to hinged armature 53. Female pin receptor 1 is connected to the Normally Open (NO) contact 54 of the armature 53. The armature 53 is connected to a tension spring that pulls the other end, or the Normally Open (NO) contact 54 of the armature 53. This is the tester 51 in its de-energized state or at rest with no voltage applied. As illustrated in FIG. 14, when the tester 51 is activated, a switch moves the hinged armature 54 down onto Normally Open (NO) female pin receptor 1. This completes the circuit between and the tester 51 is energized.

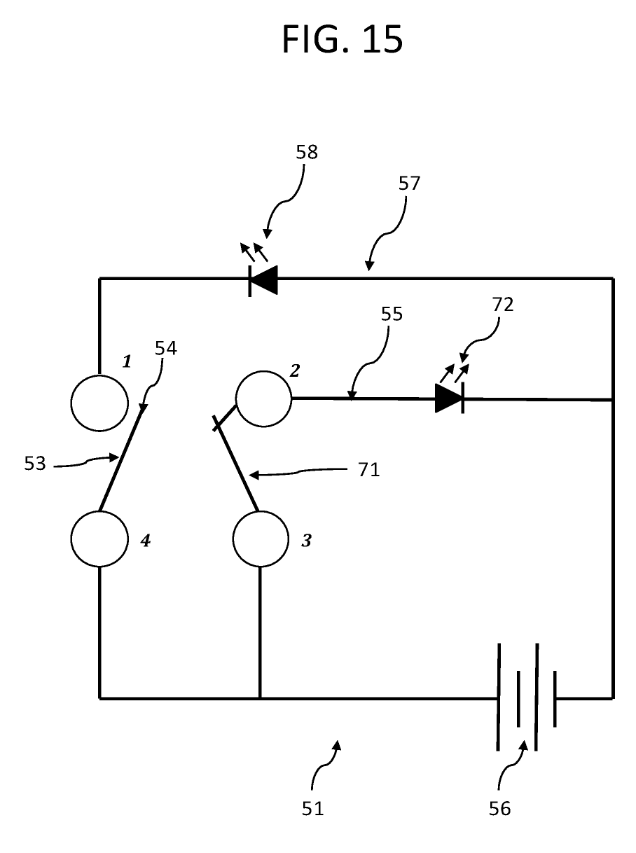

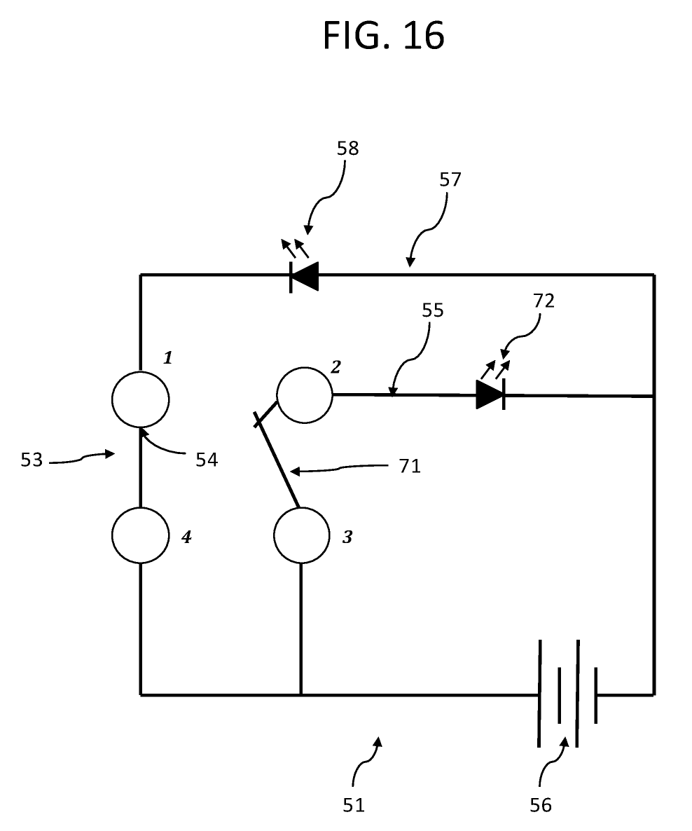

FIGS. 15 and 16 illustrate an embodiment of the troubleshooting tester device 51. In this embodiment, a connection 55 is made between pin receptor 2 and 3-volt battery 56. This connection 55 contains a first light emitting diode (LED) 72. If tester 51 receives voltage from battery 56, then connection 55 provides power to the first LED 72 to illuminate a first color on the exterior of the tester 51. Another connection 57 is made between female pin receptor 1 and battery 56. This connection 57 contains a second LED 58. If tester 51 receives voltage, a switch moves the hinged armature 53 down onto Normally Open (NO) contact 54. The connection 57 is made between female pin receptor 1 and battery 56, powering the second LED 58 to illuminate a second color on the exterior of the tester 51.

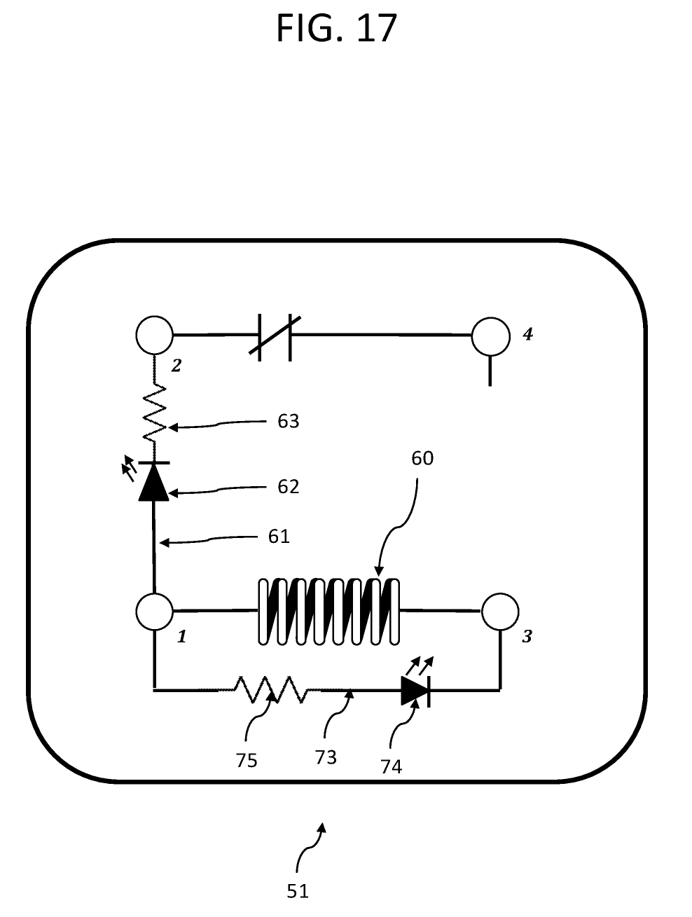

FIG. 17 illustrates another embodiment of the troubleshooting tester device 51. In this embodiment, a connection 73 is made between pin receptor 1 and pin receptor 3. This connection 73 contains a first light emitting diode (LED) 74 and a resistor 75. If tester 51 receives voltage from coil 60, then connection 73 provides power to the first LED 74 to illuminate a first color on the exterior of the tester 51. Another connection 61 is made between female pin receptor 1 and pin receptor 2. This connection 61 contains a second LED 62, and a resistor 63. If tester 51 receives voltage, the connection 61 is made between female pin receptor 1 and pin receptor 2, powering the second LED 62 to illuminate a second color on the exterior of the tester 51. The troubleshooting relay device 51 may also be used on electrical systems that are AC 120 volts and 10 to 30 amps.

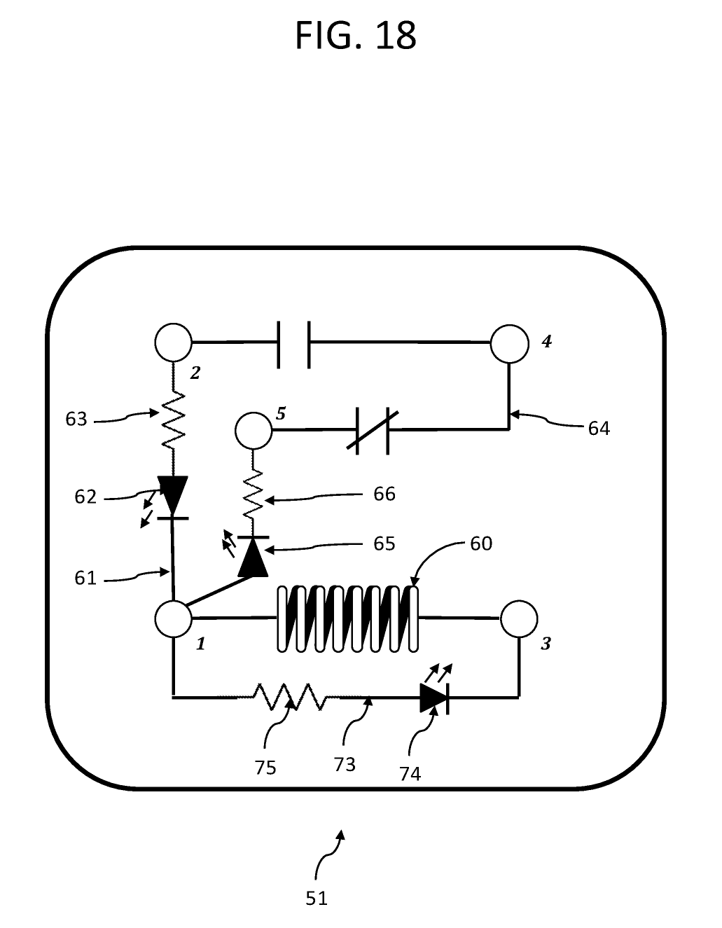

FIG. 18 illustrates a further embodiment of the troubleshooting tester device 51. In this embodiment, a connection 73 is made between pin receptor 1 and pin receptor 3. This connection 73 contains a first light emitting diode (LED) 74 and a resistor 75. If tester 51 receives voltage from coil 60, then connection 73 provides power to the first LED 7 to illuminate a first color on the exterior of the tester 51. Another connection 61 is made between female pin receptor 1 and pin receptor 2. This connection 61 contains a second LED 62, and a resistor 63. If tester 51 receives voltage, the connection 61 is made between female pin receptor 1 and pin receptor 2, powering the second LED 62 to illuminate a second color on the exterior of the tester 51. A third connection 64 is made between female pin receptor 1, pin receptor 4, and a pin receptor 5. This connection 64 contains a third LED 65, and a resistor 66. If tester 51 receives voltage, the connection 64 is made between female pin receptor 1 and pin receptor 4, powering the third LED 65 to illuminate a third color on the exterior of the tester 51. The troubleshooting relay device 51 may also be used on electrical systems that are AC 120 volts and 10 to 30 amps.

In embodiments of the subject invention, the term “vehicle” shall expressly include, but not be limited by, any land-based vehicles having pneumatic tires, any rail-based vehicles, any maglev vehicles, automobiles, cars, trucks, station wagons, sport-utility vehicles (SUVs), recreational vehicles, construction vehicles, off road vehicles, all-terrain vehicles, farm vehicles, fleet vehicles, motor homes, vans, buses, motorcycles, scooters, mopeds, campers, trailers, bicycles, a marine vehicle, an air vehicle, spacecraft, airplanes, jets, aircraft, airships, balloons, blimps, dirigibles, or another motor vehicle.

In embodiments of the subject invention, the term “substantially” is defined as at least close to (and can include) a given value or state, as understood by a person of ordinary skill in the art. In one embodiment, the term “substantially” refers to ranges within 10%, preferably within 5%, more preferably within 1%, and most preferably within 0.1% of the given value or state being specified.

The many aspects and benefits of the invention are apparent from the detailed description, and thus, it is intended for the following claims to cover such aspects and benefits of the invention, which fall within the scope, and spirit of the invention.

In addition, because numerous modifications and variations will be obvious and readily occur to those skilled in the art, the claims should not be construed to limit the invention to the exact construction and operation illustrated and described herein. Accordingly, all suitable modifications and equivalents should be understood to fall within the scope of the invention as claimed herein.

What is claimed is:

1. A relay testing device comprising:
a portable handheld housing comprising a plurality of protruding male pins operatively connected to internal terminals;
an internal switch assembly comprising an electromagnetic coil and an armature, wherein the electromagnetic coil and armature energize the relay testing device upon successful voltage applied from a circuit board;
a first external light source on the housing, wherein the first light source illuminates upon voltage received by the electromagnetic coil; and
a second external light source on the housing, wherein the second light source illuminates upon energization of the relay testing device.

2. A relay testing device comprising:
a portable handheld housing;
a first terminal within the housing operatively connected to a first protruding male pin external to the housing, wherein the first terminal is operatively connected to a first external light source on the housing, further wherein the first light source illuminates upon voltage received by the testing device from a female socket in a circuit board;
a second terminal within the housing operatively connected to a second protruding male pin external to the housing;
a third terminal within the housing operatively connected to a third protruding male pin external to the housing, wherein the third terminal is operatively connected to a second external light source on the housing;
a fourth terminal within the housing operatively connected to a fourth protruding male pin external to the housing;
an electromagnetic coil within the housing operatively connected to at the first and second terminal, wherein the electromagnetic coil emits a small magnetic field upon receive voltage from the first terminal; and
an armature within the housing operatively connected on a first end to the third terminal, wherein the armature is configured to move an uncontacted second end to contact the fourth terminal upon application of the small magnetic field from the electromagnetic coil, further wherein the second light source illuminates upon successful contact of the second end of the armature to the fourth terminal.

3. A relay testing device comprising:
a portable handheld housing;
a first terminal within the housing operatively connected to a first protruding male pin external to the housing, wherein the first terminal is operatively connected to a first external light source and a second external light source on the housing, further wherein the first light source illuminates upon voltage applied, but not received by the testing device from a female socket in a circuit board, wherein the second light source illuminates upon voltage received by the testing device from the circuit board;
a second terminal within the housing operatively connected to a second protruding male pin external to the housing;
a third terminal within the housing operatively connected to a third protruding male pin external to the housing, wherein the third terminal is operatively connected to a third external light source on the housing;
a fourth terminal within the housing operatively connected to a fourth protruding male pin external to the housing;
an electromagnetic coil within the housing operatively connected to at the first and second terminal, wherein the electromagnetic coil emits a small magnetic field upon receive voltage from the first terminal; and
an armature within the housing operatively connected on a first end to the third terminal, wherein the armature is configured to move an uncontacted second end to contact the fourth terminal upon application of the small magnetic field from the electromagnetic coil, further wherein the third light source illuminates upon successful contact of the second end of the armature to the fourth terminal.

4. The relay testing device of claim 1, further comprising a third external light source on the housing, wherein the third light source illuminates upon energization of the relay testing device.

5. The relay testing device of claim 1, wherein the relay testing device is re-useable for testing multiple circuit boards.

6. The relay testing device of claim 1, wherein the first external light source and the second external light source each comprise light emitting diodes.

7. The relay testing device of claim 1, wherein the first external light source emits visible red light.

8. The relay testing device of claim 1, wherein the second external light source emits visible green light.

9. The relay testing device of claim 1, wherein the the first external light source and the second external light source illuminate through a single window on the exterior of the housing.

10. The relay testing device of claim 1, wherein the the first external light source and the second external light source illuminate through a two windows on the exterior of the housing.

11. The relay testing device of claim 1, wherein the relay testing device comprises the housing and male pins substantially similar to relay DIN 72552.

12. The relay testing device of claim 1, wherein the circuit board comprises a 12 volt or 24-volt board from vehicle electrical systems.

13. The relay testing device of claim 12, wherein the vehicle comprises any land-based vehicles having pneumatic tires, any rail-based vehicles, any maglev vehicles, automobiles, cars, trucks, station wagons, sport-utility vehicles (SUVs), recreational vehicles, construction vehicles, off road vehicles, all-terrain vehicles, farm vehicles, fleet vehicles, motor homes, vans, buses, motorcycles, scooters, mopeds, campers, trailers, bicycles, a marine vehicle, an air vehicle, spacecraft, airplanes, jets, aircraft, airships, balloons, blimps, dirigibles, or another motor vehicle.
